(19) United States
(12) Patent Application Publication
(10) Pub. No.: US 2019/0372054 A1
(43) Pub. Date: Dec. 5, 2019

(54) DISPLAY SCREEN, DISPLAY DEVICE AND METHOD FOR MANUFACTURING A DISPLAY SCREEN

(71) Applicant: Kunshan Go-Visionox Opto-Electronics Co., Ltd., Kunshan (CN)

(72) Inventors: Xiaoling LI, Kunshan (CN); Xiaoxu HU, Kunshan (CN); Panpan WANG, Kunshan (CN)

(21) Appl. No.: 16/541,170

(22) Filed: Aug. 15, 2019

Related U.S. Application Data
(63) Continuation of application No. PCT/CN2018/116273, filed on Nov. 19, 2018.

(30) Foreign Application Priority Data
May 14, 2018 (CN) 201810453615.8
May 14, 2018 (CN) 201810454353.7

(51) Int. Cl. H01L 51/52; H01L 27/32; H01L 51/56

(52) U.S. Cl. CPC H01L 51/5268; H01L 27/3244; H01L 2227/323; H01L 51/56; H01L 51/524

(57) ABSTRACT

The present application relates to a display screen, a display device and a method for manufacturing a display screen. The display screen comprises a contour line and an active display region. The active display region includes an edge display region close to the contour line and a main display region away from the contour line. The edge display region and the contour line are intersected. The display screen includes a light-emitting layer and a light-outputting layer having a first region, the first region of the light-outputting layer has a scattering structure provided thereon. Light emitted from the light-emitting layer is deviated from an original propagation direction after passing through the scattering structure. The first region is formed into at least a partial region on the light-outputting layer corresponding to the edge display region.

### CROSS-REFERENCES TO RELATED APPLICATIONS

This application is a continuation application of International Application No. PCT/CN2018/116273, filed on Nov. 19, 2018, entitled “DISPLAY SCREEN, DISPLAY DEVICE AND METHOD FOR MANUFACTURING A DISPLAY SCREEN”, which claims priority to Chinese Patent Application No. 201810453615.8, filed on May 14, 2018, entitled “DISPLAY SCREEN AND DISPLAY DEVICE”, and to Chinese Patent Application No. 201810454353.7, filed on May 14, 2018, entitled “DISPLAY SCREEN, DISPLAY DEVICE AND METHOD FOR MANUFACTURING A DISPLAY SCREEN”, all of which are incorporated herein by reference in their entireties.

### TECHNICAL FILED

The present application relates to the field of display technologies.

### BACKGROUND

At present, a thin film encapsulation structure of an OLED (Organic Light-Emitting Diode) device has a thin inorganic encapsulation layer with a large stress. Currently, existing systems and structures for OLED devices have been inadequate. It is desirable to have new and improved display devices and manufacturing methods thereof.

### SUMMARY

According to various embodiments of the present application, the following is provided.

A display screen is provided. The display screen comprises a contour line and an active display region. The active display region includes an edge display region close to the contour line and a main display region away from the contour line. The edge display region and the contour line are intersected.

The display screen includes a light-emitting layer and a light-outputting layer having a first region, the first region of the light-outputting layer has a scattering structure provided thereon. Light emitted from the light-emitting layer is deviated from an original propagation direction after passing through the scattering structure. The first region is formed into at least a partial region of the light-outputting layer corresponding to the edge display region.

A display screen is provided. The display screen comprises a contour line and an active display region. The active display region includes an edge display region close to the contour line and a main display region away from the contour line. The edge display region and the contour line are intersected.

The display screen includes a substrate, a light-emitting structure and a cover plate. The light-emitting structure is formed on the substrate and covered over by the cover plate. At least a part of the edge display region is provided with a scattering layer. The scattering layer is provided on a surface of the cover plate.

A display device is provided. The display device includes:

the display screen described above;

a power module configured to supply power to the display screen;

a storage module configured to store media information; and

a processing module electrically connected to the display screen, the power module and the storage module, and configured to control power supply of the power module and to display the media information on the display screen.

A method for manufacturing a display screen is provided to manufacture the display screen described above. The method for manufacturing a display screen includes:

providing a substrate on which a light-emitting structure is provided;

positioning a cover plate over the light-emitting structure, and determining a laying region of scattering particles to be laid and an adjusting degree to a display picture of an edge display region, according to a display condition of the edge display region of the light-emitting structure;

determining a particle diameter and a density of the scattering particles to be laid according to the laying region of the scattering particles to be laid and the adjusting degree; and

coating the scattering particles on a surface of the cover plate according to the laying region, the particle diameter, and the density of the scattering particles to be laid, to reduce an luminance of the display picture of the edge display region.

The details of one or more embodiments of the present application are set forth in the accompanying drawings and the description below. Other features, objects and advantages of the present application will become apparent from the description, the accompanying drawings, and the claims.

### BRIEF DESCRIPTION OF THE DRAWINGS

FIG. 1 is a top view of a microstructure of a special-shaped region of a display screen according to an embodiment of the present application.

FIG. 2 is a top view of a microstructure of another display screen according to an embodiment of the present application.

FIG. 3 is a schematic structural diagram of a display screen according to an embodiment of the present application.

FIG. 4 is a schematic structural diagram of a display screen according to another embodiment of the present application.

FIG. 5 is a comparison diagram of luminance between a display screen according to an embodiment of the present application and a display screen without providing with a scattering layer.

FIG. 6 is a flowchart of a method for manufacturing a display screen according to an embodiment of the present application.

### DETAILED DESCRIPTION OF THE INVENTION

As explained, existing OLED devices and manufactures methods are inadequate. More specifically, cracks are likely to occur around the inorganic encapsulation layer in the thin film encapsulation structure, and water and oxygen easily intrude into the OLED through the cracks, resulting in damage to the OLED device. Therefore, it is difficult to improve encapsulation reliability of the present thin film encapsulation structure.

For the convenience of understanding the present application, embodiments of the application are described more fully hereinafter with reference to the accompanying drawings. Preferable embodiments are presented in the accompanying drawings. However, the application may be embodied in many different forms and is not limited to the embodiments described herein. Rather, these embodiments are provided so that the disclosure of the present application will be more thoroughly understood.

As described in the background, with a display screen of the prior art, there is an obvious serration feeling problem when observed on a microscopic scale. The inventors have found that this problem is rooted in that: a pixel is generally of a regular rectangle, but the display screen generally has an arc contour line; therefore, the rectangular pixel cannot be perfectly matched with the arc-shaped contour line, and a jagged serration inevitably appears around a periphery of the contour line, resulting in the obvious serration feeling when the display screen is observed on a microscopic scale.

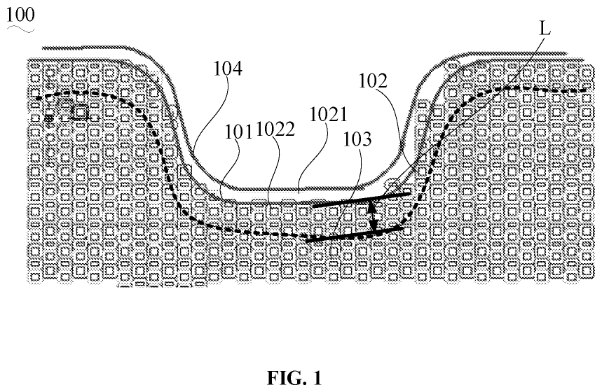

Referring to FIG. 1, FIG. 1 is a schematic top view of a partial region of a display screen 100 according to an embodiment of the present application. The display screen 100 is different from a traditional rectangular shape. Based on the traditional rectangular shape, a slot is formed at one end of the display screen 100; that is, the display screen 100 has a special-shaped shape at one end.

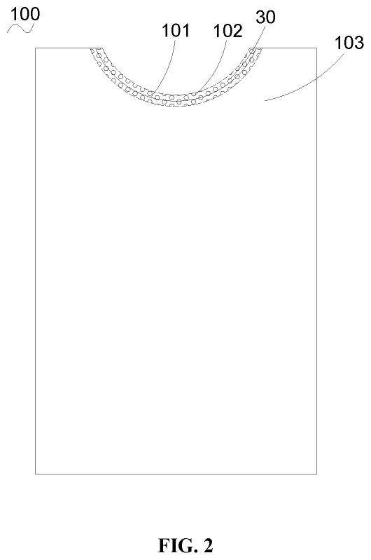

It should be understood that the display screen 100 in this embodiment may be a display screen having a slotted region (also referred to as an opening region or a bang region or a special-shaped region, the slotted region having an arc-shaped chamfer, hereinafter referred to as a slot) at one end, and may also be a display screen 100 having an arc-shaped edge chamfer (hereinafter referred to as edge chamfer) based on the traditional rectangular shape, or may also be a display screen 100 having both a slot and an edge chamfer, that is, solutions disclosed in this embodiment are applicable to a display screen 100 having an arc-shaped chamfer in any region. In the following description, only the display screen 100 having a slot shown in FIG. 2 will be described as an example.

The display screen 100 has a contour line 101 which is a boundary line of the slotted region, so as to define a range of an active display region; that is, a display screen region located inside the contour line 101 is the active display region, and a display screen region located outside the contour line 101 is an inactive display region. The active display region is configured to present an image or a dynamic display picture. The inactive display region does not need to present an image or a dynamic display picture. However, when there is a sub-pixel in the inactive display region, the image or the dynamic display picture displayed thereof will affect a display effect of the active display region, such as a serration feeling at an edge of the picture. In a specific application, the display screen 100 may be a flat screen, or a curved screen, such as a curved screen of a television, or a curved screen of a mobile phone.

The active display region includes an edge display region 102 close to the contour line 101 and a main display region 103 away from the contour line 101. The main display region 103 is adjacent to the edge display region 102. The edge display region 102 and the contour line 101 are intersected. That is, a vast part of the display screen region located inside the contour line 101 is the main display region 103, and a small part of the display screen region intersecting with the contour line 101 and located outside the contour line 101, and located inside the contour line 101 and facing towards the contour line 101 is the edge display region 102. Therefore, in this embodiment, a part 1022 of the main display region 103 and the edge display region 102 located inside an defined region of the contour line 101 is divided as the active display region, and a part 1021 located outside the contour line and a part of the edge display region 102 located outside of the defined region of the contour line 101 is divided as the inactive display region.

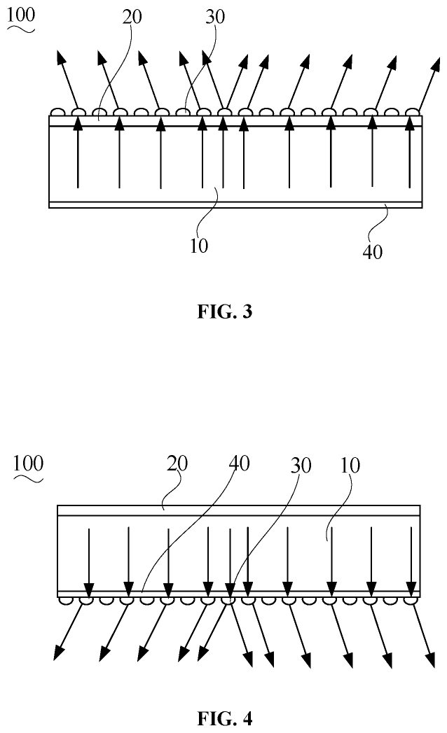

Referring to FIGS. 2 and 3, the display screen 100 includes a light-emitting layer 10 and a light-outputting layer laminated. The light-emitting layer 10 is a part of the OLED. The light-emitting layer 10 may be a laminated structure formed by laminating multiple layers. In this embodiment, the light-emitting layer 10 is a light-emitting material layer. Additionally, the OLED further includes a common layer. Specifically, the common layer includes an electron injection layer, an electron transport layer, a hole blocking layer, an electron blocking layer, a hole transport layer and a hole injection layer, and the like. More specifically, the light-emitting layer is provided between a laminated layer formed by the electron injection layer, the electron transport layer and the hole blocking layer, and a laminated layer formed by the electron blocking layer, the hole transport layer and the hole injection layer.

The OLED is a carrier double-injection type light-emitting device. Under driving at an external voltage, electrons and holes injected by an electrode recombine in an organic material to release energy and the energy is transferred to molecules of organic light-emitting substance, so that the molecules of the organic light-emitting substance are excited to transition from a ground state to an excited state. The excited molecules, when return from the excited state to the ground state, radiate and emit light.

Specifically, a scattering structure 30 is provided on a first region of the light-outputting layer. Light emitted from the light-emitting layer 10 is deviated from an original propagation direction after passing through the scattering structure 30. The first region is formed into at least a partial region of the light-outputting layer corresponding to the edge display region 102. Specifically, referring to FIG. 1, the first region may be a light-outputting layer region corresponding to the part 1021 of the edge display region 102 located outside the defined region of the contour line 101 (that is, the part between the contour line 101 and a curved line 104), and may also be a light-outputting layer region corresponding to the edge display region 102. This embodiment is not limited thereto, and is specifically described in the following description of the embodiments. Thus, due to the presence of the scattering structure 30, the light may be deviated from the original propagation direction when passing through the scattering structure 30 (at least part of the light is no longer perpendicular to the light-outputting layer after passing through the scattering structure 30). Therefore, part of the light from the edge display region 102 is propagated to a non-display region of the display screen 100, thereby reducing an amount of the light outputted from the edge display region 102, making a natural transition of luminance from the edge display region 102 to the non-display region, and thus reducing the edge serration feeling of the display screen 100.

It should be understood that, for the display screen with different structure, the light-outputting layer is structurally different. For example, for a top light-emitting display screen, the light-outputting layer may be at least one layer of a light extraction layer, a negative electrode and a top cover plate. For a bottom light-emitting structure, the light-outputting layer may be a positive electrode and/or a bottom cover plate. This embodiment is not limited thereto, and is described respectively in the following description of the embodiments.

Specifically, referring to FIG. 3, FIG. 3 is a schematic cross-sectional view of an edge region of a top light-emitting display screen disclosed in an embodiment of the present application. The light-outputting layer in this embodiment is the negative electrode 20. The negative electrode 20 is an integral structure, and is provided on the light-emitting layer 10. The negative electrode 20 is contacted with an electrode power supply line outside the display region, thereby the electrode power supply line may receive an electric signal. When the display screen 100 is the top light-emitting display screen (that is, the display screen with a top light-emitting structure), the light emitted from the light-emitting layer 10 is emitted from the negative electrode 20 in a direction perpendicular to the negative electrode 20. The scattering structure 30 is provided on the first region of the negative electrode 20. The light emitted from the light-emitting layer 10 is deviated from the original propagation direction after passing through the scattering structure 30.

More specifically, the above-described scattering structure 30 may be provided on an upper surface (a surface facing away from a surface of the light-emitting layer 10) of the first region of the negative electrode 20, on a lower surface (a surface facing towards the surface of the light-emitting layer 10) of the first region of the negative electrode 20, or on both the upper and lower surfaces of the first region of the negative electrode 20, which may be selected according to actual needs, and this embodiment is not limited thereto.

Thus, due to the presence of the scattering structure 30, the light may be deviated from the original propagation direction when passing through the scattering structure 30 (at least a part of the light is no longer perpendicular to the negative electrode 20 after passing through the scattering structure 30). Therefore, the part of the light from the edge display region 102 is propagated to a non-display region of the display screen 100, thereby reducing an amount of the light outputted from the edge display region 102, making a natural transition of luminance from the edge display region 102 to the non-display region, and thus reducing the edge serration feeling of the display screen 100.

Specifically, in this embodiment, the scattering structure 30 is a concave-convex structure provided in the first region of the negative electrode 20.

More specifically, the above-described concave-convex structure may be formed on the upper surface of the first region of the negative electrode 20 by means of embossing. Embossing is a process in which a material has a thickness changed under action of a mold and a undulating pattern or a character is embossed on a surface of the material.

In another embodiment, the above-described concave-convex structure may be formed on the upper surface of the first region of the negative electrode 20 by means of etching.

A specific process may be: spin-coating a photoresist on the entire display screen, and then exposing and developing the photoresist by using a mask plate having an opening of a pattern of the active display region as a mask, to expose the inactive display region to be etched, and forming a photoresist layer having an opening of the pattern of the active display region on the entire display screen; and then forming the above-described concave-convex structure on the exposed inactive display region to be etched by the etching process and by using the photoresist layer having the opening of the pattern of the active display region as a mask; after forming the concave-convex structure, removing the photoresist layer.

In another embodiment, the above-described scattering structure 30 is formed by evaporating a scattering particle layer on the upper surface (facing away from the surface of the light-emitting layer 10) of the first region of the negative electrode 20. When the light passes through the scattering particle layer, the light is scattered by the scattering particle layer, and thus part of the light is inevitably emitted to the non-display region, making a natural transition of luminance from the edge display region 102 to the non-display region.

It should be understood that, in other embodiments, the above-described scattering structure 30 may be formed by evaporating the scattering particle layer on the lower surface (facing towards the surface of the light-emitting layer 10) of the first region of the negative electrode 20, or may be formed by evaporating the scattering particle layers both on the upper surface and the lower surface of the first region of the negative electrode.

Specifically, the scattering particle layer is one or more of organic silicone, polyethylene, acrylic resin, nano-barium sulfate, silicon dioxide and calcium carbonate.

Specifically, a scattering effect of the scattering structure 30 is in direct proportion to a particle diameter of scattering particles of the scattering particle layer, and the scattering effect of the scattering structure 30 is in direct proportion to a density of the scattering particles of the scattering particle layer. The density is defined as a percentage of an area of the scattering particles occupying the part of the negative electrode 20 provided with the scattering structure 30. When the serration feeling is slight, particles having a small particle diameter and a small density are selected, and when the serration feeling is severe, particles having a large particle diameter and a large density are selected.

More specifically, the scattering particles having a particle diameter of 5 um to 100 um are selected, but no scattering particle having an excessively large particle diameter should be selected. Selection is based on actual needs. The density (a degree of denseness) of the scattering particles ranges from 10% to 40%, but no scattering particles having an excessively high density should be selected. The scattering particles are selected as long as suitable. The density of the scattering particles is defined as a ratio of an area of the scattering particles occupying the light-outputting layer to an area of a part of the light-outputting layer provided with the scattering structure. For example, as shown in FIG. 1, if the scattering particles are only provided between the contour line 101 and the curved line 104, the density of the scattering particles is equal to: the total area of the scattering particles: an area of a cover plate region located between the contour line 101 and the curved line 104.

Further, the display screen 100 further includes a pixel define layer (PDL) (not shown) and a top cover plate (not shown). The display screen 100 further includes some pixel units arranged repeatedly. The pixel units include a first sub-pixel, a second sub-pixel and a third sub-pixel. The pixel define layer is provided with openings corresponding to each of the sub-pixels (that is, the openings exposing a central part of each of the sub-pixels) and configured to define the sub-pixels. The first sub-pixel, the second sub-pixel, and the third sub-pixel are provided in the corresponding openings respectively. The top cover plate is configured to protect the light-emitting layer 10 and other structural layer of the display screen 100.

In this embodiment, a normal distance L between the edge display region 102 and the contour line 101 is less than a preset distance threshold, so as to determine that whether or not a pixel unit is located in the edge display region 102. For example, it is found from statistical data that for a pixel unit of a specific size, the contour line 101, when offset inward by 3 mm, reaches the main display region 103, and therefore the preset distance threshold may be set as 3 mm.

Definitely, the preset distance threshold of 3 mm is only an example. A specific value range of the preset distance threshold is related to a curvature of the contour line and the size of the pixel unit.

The display screen 100 further includes a substrate (not shown), a thin-film transistor (TFT) (not shown) and a positive electrode 40. The thin-film transistor is provided on the substrate. The positive electrode 40 is provided on the thin-film transistor. The light-emitting layer 10 is provided on the positive electrode 40.

The substrate has a first sub-pixel region, a second sub-pixel region and a third sub-pixel region. A set of the first sub-pixel region, the second sub-pixel region and the third sub-pixel region may constitute a pixel region. The substrate may have a plurality of pixel regions. The thin-film transistor controls emission from each of the sub-pixels, or may control an amount of emission when each of the sub-pixels emits the light.

Specifically, in this embodiment, a part of the edge display region 102 and the contour line 101 are intersected, thus the edge display region 102 has the part 1021 located outside the defined region of the contour line 101. The scattering structure 30 is provided on a surface of a region of the negative electrode 20 corresponding to the part 1021 of the edge display region 102 located outside the defined region of the contour line 101 (that is, the part between the contour line 101 and the curved line 104). That is, the first region of the negative electrode 20 is a negative electrode region corresponding to the part 1021 of the edge display region 102 located outside the defined region of the contour line 101. In other words, no scattering structure 30 is provided on a surface of the negative electrode 20 of the part 1022 of the edge display region 102 located inside the defined region of the contour line 101. That is, in this embodiment, a projection of the first region of the negative electrode 20 on the substrate of the display screen 100 is a first projection, a projection of the part 1021 of the edge display region 102 located outside the defined region of the contour line 101 on the substrate of the display screen 100 is a third projection, and the first projection overlaps the third projection.

In other embodiments, it may be provided that as long as the scattering structure 30 is provided on the surface of the negative electrode 20 located in the edge display region 102, i.e., when a projection of the first region of the negative electrode 20 on the substrate of the display screen 100 is a first projection, and a projection of the edge display region 102 on the substrate of the display screen 100 is a second projection, the first projection overlaps the second projection, which is not limited thereto.

In a specific application, when a ratio of a pixel unit in the part 1021 outside the defined region of the contour line 101 to that in the part 1022 inside the defined region of the contour line 101 exceeds a value, such as 50%, the pixel unit is divided as an invalid pixel unit, so as to remove the pixel unit (that is, the pixel unit is not evaporated), and when the ratio is less than the value, the pixel unit is retained.

The positive electrode 40 includes a first sub-pixel electrode, a second sub-pixel electrode, and a third sub-pixel electrode. The first sub-pixel electrode is formed in the first sub-pixel region, the second sub-pixel electrode is formed in the second sub-pixel region, and the third sub-pixel electrode is formed in the third sub-pixel region. Each of the first sub-pixel electrode, the second sub-pixel electrode and the third sub-pixel electrode may be electrically connected to the thin-film transistor through a via.

In another embodiment, the display screen 100 is the top light-emitting structure, the light-outputting layer is a light extraction layer which is an integral structure, and the light emitted from the light-emitting layer 10 is emitted from the light extraction layer in a direction perpendicular to the light extraction layer. The scattering structure 30 is provided on the first region of the light extraction layer. The light emitted from the light-emitting layer 10 is deviated from the original propagation direction after passing through the scattering structure 30.

Specifically, the same as the above-described embodiments, the scattering structure 30 may be provided on an upper surface of the first region of the light extraction layer, may also be provided on a lower surface of the first region of the light extraction layer, and may further be provided on both the upper surface and the lower surface of the first region of the light extraction layer.

More specifically, the scattering structure 30 is a concave-convex structure provided on the first region of the light extraction layer. The concave-convex structure is formed on a surface of the first region of the light extraction layer by means of embossing or etching. Alternatively, the scattering structure 30 is a scattering particle layer formed on the first region of the light extraction layer by an evaporation process.

Specifically, in this embodiment, the edge display region 102 and the contour line 101 are intersected, and thus the edge display region 102 has the part 1021 located outside the defined region of the contour line 101. The scattering structure 30 is provided on a surface of the light extraction layer of the part 1021 of the edge display region 102 located outside the defined region of the contour line 101 (that is, the part between the contour line 101 and the curved line 104). That is, no scattering structure 30 is provided on a surface of the light extraction layer of the part 1022 of the edge display region 102 located inside the defined region of the contour line 101. That is, when a projection of the first region of the light extraction layer on the substrate of the display screen 100 is a first projection, and a projection of the part 1021 of the edge display region 102 located outside of the defined region of the contour line 101 on the substrate of the display screen 100 is a third projection, the first projection overlaps the third projection. In other embodiments, it may be provided that as long as the scattering structure 30 is provided on the surface of the light extraction layer located in the edge display region 102, i.e., when a projection of the first region of the light extraction layer on the substrate of the display screen 100 is a first projection, and a projection of the edge display region 102 on the substrate of the display screen 100 is a second projection, the first projection overlaps the second projection, which is not limited thereto.

In another embodiment, the display screen 100 is the top light-emitting structure, the light-outputting layer is a top cover plate which is an integral structure, and the light emitted from the light-emitting layer 10 is emitted from the top cover plate in a direction perpendicular to the top cover plate. The scattering structure 30 is provided on the first region of the top cover plate. The light emitted from the light-emitting layer 10 is deviated from the original propagation direction after passing through the scattering structure 30.

Specifically, the same as the above-described embodiments, the scattering structure 30 may be provided on an upper surface of the first region of the top cover plate, may also be provided on a lower surface of the first region of the top cover plate, and may further be provided on both the upper surface and the lower surface of the first region of the top cover plate.

More specifically, the scattering structure 30 is a concave-convex structure provided on the first region of the top cover plate. The concave-convex structure is formed on the first region of the top cover plate by means of embossing or etching. Alternatively, the scattering structure 30 is a scattering particle layer formed on the first region of the top cover plate by an evaporation process.

More specifically, in this embodiment, the edge display region 102 and the contour line 101 are intersected, and thus the edge display region 102 has the part 1021 located outside the defined region of the contour line 101. The scattering structure 30 is provided on a surface of the top cover plate corresponding to the part 1021 of the edge display region 102 located outside the defined region of the contour line 101 (that is, the part between the contour line 101 and the curved line 104). That is, no scattering structure 30 is provided on a surface of the top cover plate of the part 1022 of the edge display region 102 located inside the defined region of the contour line 101. That is, when a projection of the first region of the top cover plate on the substrate of the display screen 100 is a first projection, and a projection of the part 1021 of the edge display region 102 located outside of the defined region of the contour line 101 on the substrate of the display screen 100 is a third projection, the first projection overlaps the third projection.

In other embodiments, it may be provided that as long as the scattering structure 30 is provided on the surface of the top cover plate located in the edge display region 102, i.e., when a projection of the first region of the top cover plate on the substrate of the display screen 100 is a first projection, and a projection of the edge display region 102 on the substrate of the display screen 100 is a second projection, the first projection overlaps the second projection, which is not limited thereto.

It should be understood that, when the display screen 100 is the top light-emitting structure, the scattering structure 30 may be selectively provided on respective layer over the light-emitting layer 10. Cases where the scattering structure 30 is provided for other structural layers will not be described in detail herein.

In addition, when the display screen 100 is the top light-emitting structure, the solution that the scattering structure 30 is provided on the first region of the light-outputting layer in the above embodiments may be used alone or in combination, as long as the scattering structure 30 is provided on the first region of the light-outputting layer on the basis of ensuring the performance of the display screen 100.

Referring to FIG. 4, FIG. 4 is a schematic cross-sectional view of an edge region of a bottom light-emitting display screen. In another embodiment, the light-outputting layer is the positive electrode 40. In contrast to the above embodiments, the display screen 100 in this embodiment is a bottom light-emitting display screen (that is, a display screen of a bottom light-emitting structure); that is, the light emitted from the light-emitting layer 10 is emitted from the positive electrode 40 in a direction perpendicular to the positive electrode 40. The scattering structure 30 is provided on the first region of the positive electrode 40. The light emitted from the light-emitting layer 10 is deviated from the original propagation direction after passing through the scattering structure 30.

More specifically, the above-described scattering structure 30 may be provided on an upper surface (the surface facing towards a surface of the light-emitting layer 10) of the first region of the positive electrode 40, may also be provided on a lower surface (the surface facing away from the surface of the light-emitting layer 10) of the first region of the positive electrode 40, and may also be provided on both the upper surface and the lower surface of the first region of the positive electrode 40, which may be selected according to actual needs.

Thus, due to the presence of the scattering structure 30, the light may be deviated from the original propagation direction when passing through the scattering structure 30 (at least part of the light is no longer perpendicular to the positive electrode 40 after passing through the scattering structure 30). Therefore, part of the light from the edge display region 102 is propagated to a non-display region of the display screen 100, thereby reducing an amount of the light outputted from the edge display region 102, making a natural transition of luminance from the edge display region 102 to the non-display region, and thus reducing the edge serration feeling of the display screen 100.

In this embodiment, the above-described scattering structure 30 is formed by evaporating a scattering particle layer on a lower surface of the first region of the positive electrode 40 (the surface facing away from a surface of the light-emitting layer 10). When the light passes through the scattering particle, the light is scattered by the scattering particle, and thus part of the light is inevitably emitted to the non-display region, making a natural transition of luminance from the edge display region 102 to the non-display region. In other embodiments, the above-described scattering structure 30 may be formed by evaporating the scattering particle layer on an upper surface of the first region of the positive electrode 40 (the surface facing towards the surface of the light-emitting layer 10), which is not limited thereto.

In other embodiments, the scattering structure 30 is a concave-convex structure provided on the first region of the positive electrode 40. Specifically, the concave-convex structure is formed on the surface of the positive electrode 40 by embossing or etching.

The display screen 100 further includes a substrate (not shown) and a thin-film transistor (TFT) (not shown). The thin-film transistor is provided on the substrate. The positive electrode 40 is provided on the thin-film transistor. The light-emitting layer 10 is provided on the positive electrode 40.

Specifically, in this embodiment, the edge display region 102 and the contour line 101 are intersected, and thus the edge display region 102 has the part 1021 located outside the defined region of the contour line 101. The scattering structure 30 is provided on a surface of the positive electrode 40 of the part 1021 of the edge display region 102 located outside the defined region of the contour line 101 (that is, the part between the contour line 101 and the curved line 104). That is, no scattering structure 30 is provided on a surface of the positive electrode 40 of the part 1022 of the edge display region 102 located inside the defined region of the contour line 101. That is, when a projection of the first region of the positive electrode 40 on the substrate of the display screen 100 is a first projection, and a projection of the part 1021 of the edge display region 102 located outside of the defined region of the contour line 101 on the substrate of the display screen 100 is a third projection, the first projection overlaps the third projection. In other embodiments, it may be provided that as long as the scattering structure 30 is provided on the surface of the positive electrode 40 located in the edge display region 102, that is, when a projection of the first region of the positive electrode 40 on the substrate of the display screen 100 is a first projection, and a projection of the edge display region 102 on the substrate of the display screen 100 is a second projection, the first projection overlaps the second projection, which is not limited thereto.

Further, the display screen 100 further includes a pixel define layer (PDL) (not shown) and a negative electrode 20. The arrangement of the pixel define layer (PDL) and the negative electrode may refer to the above-described embodiments, which is not described in detail herein.

In another embodiment, the display screen 100 is the bottom light-emitting structure, the light-outputting layer is a bottom cover plate which is an integral structure, and the light emitted from the light-emitting layer 10 is emitted from the bottom cover plate in a direction perpendicular to the bottom cover plate. The scattering structure 30 is provided on the first region of the bottom cover plate. The light emitted from the light-emitting layer 10 is deviated from the original propagation direction after passing through the scattering structure 30.

Specifically, the same as the above-described embodiments, the scattering structure 30 may be provided on an upper surface of the first region of the bottom cover plate, may also be provided on a lower surface of the first region of the bottom cover plate, and may further be provided on both the upper surface and the lower surface of the first region of the bottom cover plate 30.

In addition, the scattering structure 30 is a concave-convex structure provided on the first region of the bottom cover plate. The concave-convex structure is formed on the surface of the first region of the bottom cover plate by means of embossing or etching. Alternatively, the scattering structure 30 is a scattering particle layer formed on the first region of the bottom cover plate by an evaporation process.

More specifically, in this embodiment, the edge display region 102 and the contour line 101 are intersected, and thus the edge display region 102 has the part 1021 located outside the defined region of the contour line 101. The scattering structure 30 is provided on a surface of the bottom cover plate of the part 1021 of the edge display region 102 located outside the defined region of the contour line 101 (that is, the part between the contour line 101 and the curved line 104). That is, no scattering structure 30 is provided on a surface of the bottom cover plate of the part 1022 of the edge display region 102 located inside the defined region of the contour line 101. That is, when a projection of the first region of the bottom cover plate on the substrate of the display screen 100 is a first projection, and a projection of the part 1021 of the edge display region 102 located outside of the defined region of the contour line 101 on the substrate of the display screen 100 is a third projection, the first projection overlaps the third projection. In other embodiments, it may be provided that as long as the scattering structure 30 is provided on the surface of the bottom cover plate located in the edge display region 102, i.e., when a projection of the first region of the bottom cover plate on the substrate of the display screen 100 is a first projection, and a projection of the edge display region 102 on the substrate of the display screen 100 is a second projection, the first projection overlaps the second projection, which is not limited thereto.

It should be understood that, when the display screen 100 is the bottom light-emitting structure, the scattering structure 30 may be selectively provided on respective layer underneath the light-emitting layer. Cases where the scattering structure 30 is provided for other structural layers will not be described in detail herein.

In addition, when the display screen 100 is the bottom light-emitting structure, the solution that the scattering structure 30 is provided on the first region of the light-outputting layer in the above embodiments may be used alone or in combination, as long as the scattering structure 30 is provided on the first region of the light-outputting layer on the basis of ensuring the performance of the display screen 100.

In the display screen 100 provided in the embodiments of the present application, due to the presence of the scattering structure 30, the light may be deviated from the original propagation direction when passing through the scattering structure 30 (at least part of the light is no longer perpendicular to the light-outputting layer after passing through the scattering structure 30). Therefore, part of the light from the edge display region 102 is propagated to a non-display region of the display screen 100, thereby reducing an amount of the light outputted from the edge display region 102, making a natural transition of luminance from the edge display region 102 to the non-display region, and thus reducing the edge serration feeling of the display screen 100.

In another embodiment, the display screen 100 includes a substrate, a light-emitting structure and a cover plate. The light-emitting structure is formed on the substrate. The cover plate is provided at a distance from the light-emitting structure.

The substrate may be formed of a suitable material, such as a glass material, a metal material, or a plastic material including polyethylene terephthalate (PET), polyethylene naphthalate (PEN), polyimide and the like.

Specifically, the substrate includes a first sub-pixel region, a second sub-pixel region and a third sub-pixel region. A set of the first sub-pixel region, the second sub-pixel region and the third sub-pixel region constitutes a pixel region. The substrate has a plurality of pixel regions.

More specifically, the first sub-pixel region is a sub-pixel region emitting red light, the second sub-pixel region is a sub-pixel region emitting green light and the third sub-pixel region is a sub-pixel region emitting blue light.

In this embodiment, the display screen 100 further includes a thin-film transistor (TFT). The thin-film transistor is provided on the substrate. The light-emitting structure is provided on the thin-film transistor. The thin-film transistor may control emission of each of the sub-pixels, or may control an amount of emission when each of the sub-pixels emits the light. The specific structure of the thin-film transistor can be referred to the prior art, and are not described in details herein again.

In this embodiment, the light-emitting structure includes the positive electrode, a hole injection layer, a hole transport layer, an electron blocking layer, the light-emitting layer, an hole blocking layer, an electron transport layer, an electron injection layer, and the negative electrode sequentially laminated from a side close to the substrate to a side away from the substrate. Holes are injected to the hole injection layer by the positive electrode and to the light-emitting layer through the hole transport layer. Electrons are injected to the electron injection layer by the negative electrode and to the light-emitting layer through the electron transport layer. The electrons and the holes recombine in the light-emitting layer to release energy and the energy is transferred to molecules of the light-emitting layer, so that the molecules of the light-emitting layer are excited to transition from a ground state to an excited state. The excited molecules, when return from the excited state to the ground state, radiate and emit light.

The display screen 100 further includes a pixel define layer (PDL). The display screen 100 includes some pixel units arranged repeatedly. Each of the pixel unit includes a first sub-pixel, a second sub-pixel and a third sub-pixel. The pixel define layer is provided with openings corresponding to each of the sub-pixels (that is, openings exposing a central part of the each of the sub-pixel), and configured to define the sub-pixels. The first sub-pixel, the second sub-pixel, and the third sub-pixel are provided in the corresponding openings respectively.

Specifically, the first sub-pixel is a red sub-pixel, the second sub-pixel is a green sub-pixel and the third sub-pixel is a blue sub-pixel. A luminescent material emitting red light, green light, and blue light may be evaporated in the above-described openings using a precision metal mask to form the red sub-pixel, the green sub-pixel, and the blue sub-pixel, respectively. Each of the pixel units corresponds to each of the pixel regions on the substrate, and the first sub-pixel, the second sub-pixel and the third sub-pixel in each of the pixel units respectively correspond to the first sub-pixel region, the second sub-pixel region, and the third sub-pixel region in the corresponding pixel region.

The cover plate is provided on the light-emitting structure to protect the light-emitting structure and other structural layers of the display screen 100. The light emitted from the light-emitting layer is propagated out of the display screen from the cover plate in a direction perpendicular to the cover plate.

Specifically, in this embodiment, the display screen 100 further includes a scattering layer. The scattering layer is provided on a surface of the cover plate of at least a part of the edge display region 102.

Thus, due to the presence of the scattering layer, the light may be deviated from the original propagation direction when passing through the scattering layer (at least part of the light is no longer perpendicular to the cover plate after passing through the scattering layer). Therefore, part of the light from the edge display region 102 is propagated to a non-display region of the display screen 100, thereby reducing an amount of the light outputted from the edge display region 102, and the presence of the scattering layer may blur the image, thereby making a natural transition of luminance from the edge display region 102 to the non-display region, and thus reducing the edge serration feeling of the display screen 100.

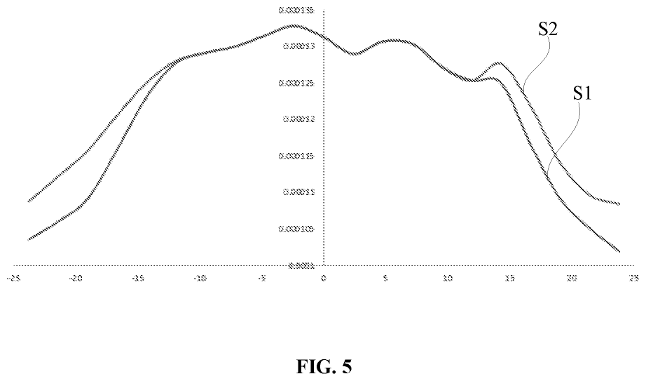

Referring to FIG. 5, a horizontal axis represents a distance between a pixel unit located in the edge display region 102 and a pixel unit located at the center of the main display region 103, and a vertical axis represents a luminance value. The display screen 100 provided in an embodiment of the present application has a first luminance curved line 51, and a display screen of the prior art providing with no scattering layer has a second luminance curved line S2. The luminance of the first luminance curved line 51 is obviously lower than that of the second luminance curved line S2, thus the result is consistent with the above analysis result, thereby demonstrating that the scattering layer may reduce the luminance of the edge display region 102.

In this embodiment, a normal distance L between the edge display region 102 and the contour line 101 is less than a preset distance threshold, so as to determine that whether or not a pixel unit is located in the edge display region 102. For example, it is found from statistical data that for a pixel unit of a specific size, the contour line 101, when offset inward by 3 mm, reaches the main display region 103, therefore the preset distance threshold may be set as 3 mm. Definitely, the preset distance threshold of 3 mm is only an example. A specific value range of the preset distance threshold is related to a curvature of the contour line 101, the size of the pixel unit and the arrangement of the pixel unit.

Further, since the edge display region 102 and the contour line 101 are intersected, it may be indicate that there is a sub-pixel in the edge display region 102 bordering on the contour line 101, and the sub-pixel bordering on the contour line 101 may be one or more types of the first sub-pixel and the second sub-pixel and the third sub-pixel.

Specifically, in this embodiment, the scattering layer is provided on the cover plate of the part 1021 of the edge display region 102 located outside the defined region of the contour line 101 (the part located between the contour line 101 and the curved line 104), which means that no scattering layer is provided on the cover plate of the part 1022 of the edge display region 102 located inside the defined region of the contour line 101. In other embodiment, the scattering layer may be provided throughout the cover plate located in the edge display region 102, which is not limited thereto.

In a specific application, when a ratio of a pixel unit that in the part 1021 outside the defined region of the contour line 101 to that in the part 1022 inside the defined region of the contour line 101 exceeds a value, such as 50%, the pixel unit is divided as an invalid pixel unit, so as to remove the pixel unit (that is, the pixel unit is not evaporated), and when the ratio is less than the value, the pixel unit is retained.

Further, the scattering layer is provided on a surface of the cover plate facing towards the light-emitting structure, that is, the scattering layer is provided on a lower surface of the cover plate during normal use. It should be understood that, in other embodiments, the scattering layer may also be selectively provided on a surface of the cover plate facing away from the light-emitting structure; that is, the scattering layer is provided on an upper surface of the cover plate during normal use. In other embodiments, the scattering layer may also be provided on both the upper surface and the lower surface of the cover plate.

Specifically, the scattering layer is a scattering particle layer. The scattering particles are one or more of organic silicone, polyethylene, acrylic resin, nano-barium sulfate, silicon dioxide and calcium carbonate. It should be understood that, the scattering particles may be selectively made of other materials in addition to the types listed above, which is not described in detail herein.

Specifically, a scattering effect of the scattering layer is in direct proportion to a particle diameter of the scattering particles, and the scattering effect of the scattering layer is in direct proportion to a density of the scattering particles. The density of the scattering particles is defined as a ratio of an area of the scattering particles occupying the cover plate to an area of the part of the cover plate provided with the scattering layer. For example, as shown in FIG. 5, if the scattering particles are only provided between the contour line 101 and the curved line 104, the density of the scattering particles is equal to: the total area of the scattering particles: the area of a cover plate region located between the contour line 101 and the curved line 104.

More specifically, the scattering particles having a particle diameter of 5 um to 100 um are selected, and the density (denseness degree) of the scattering particles is 10% to 40%.

In the display screen disclosed in the embodiments of the present application, due to the presence of the scattering layer, the light may be deviated from the original propagation direction when passing through the scattering layer (at least part of the light is no longer perpendicular to the cover plate after passing through the scattering layer). Therefore, part of the light from the edge display region is propagated to a non-display region of the display screen, thereby reducing an amount of the light outputted from the edge display region, and the presence of the scattering layer may blur the image, thereby making a natural transition of luminance from the edge display region to the non-display region, and thus reducing the edge serration feeling of the display screen.

A person skilled in the art may understand that, for display screens with different shapes, the scattering particles are provided in different regions; however, the scattering particles are provided either in the entire edge display region or in the edge display region outside the contour line (that is, the part located between the contour line 101 and the curved line 104 in FIG. 1).

For example, for a display screen having both a slot and an edge chamfer, the scattering particles are provided on not only the edge display region in the slotted region (the slotted region also has an arc chamfer), but also the edge display region in the edge chamfer, thereby reducing the serration feeling of the edge region. For a display screen having only an edge chamfer, the scattering particles are provided only on the edge display region in the edge chamfer; and for a display screen having only a slotted region, and edges are regular right-angles, the scattering particles are provided only on the slotted region.

An embodiment of the present application further provides a display device including the display screen 100 of any one of the above-described embodiments. The display device further includes a power module, a storage module and a processing module. The power module is configured to supply power to the display screen 100. The storage module is configured to store media information. The processing module is electrically connected to the display screen, the power module and the storage module, and is configured to control the power supply of the power module, and to display the media information on the display screen 100.

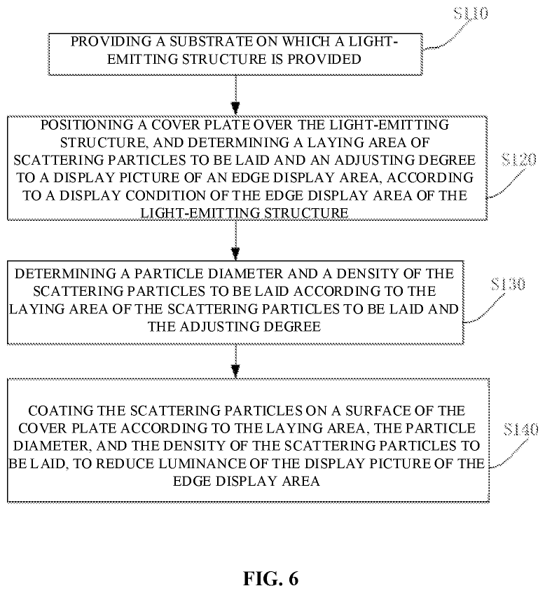

Referring to FIG. 6, a method for manufacturing a display screen is provided according to an embodiment of the present application. It should be understood that although the various steps in the flowchart of FIG. 6 are sequentially shown as indicated by the arrows, these steps are not necessarily performed in the order indicated by the arrows. Unless explicitly stated herein, the performing order of these steps is not be limited strictly, and the steps may be performed in other orders. Moreover, at least some steps in FIG. 6 may include a plurality of sub-steps or a plurality of phases, which are not necessary to be performed simultaneously, but may be performed at different times, and for the performing order thereof, it is not necessary to be performed sequentially, but may be performed by turns or alternately with other steps or at least some sub-steps or phases of other steps.

The method for manufacturing a display screen includes steps:

S110: providing a substrate on which a light-emitting structure is provided.

S120: positioning a cover plate over the light-emitting structure, and determining a laying region of scattering particles to be laid and an adjusting degree to a display picture of an edge display region, according to a display condition of the edge display region of the light-emitting structure.

Specifically, after positioning the cover plate on the light-emitting structure, the light-emitting structure emits light, and there is a serration picture in the edge display region of the light-emitting structure. The laying region of the scattering particles on the cover plate and the adjusting degree to the display picture of an edge display region may be determined according to the display condition of the serration picture on the cover plate, so as to prepare for the subsequent work.

S130: determining a particle diameter and a density of the scattering particles to be laid according to the laying region of the scattering particles to be laid and the adjusting degree.

Specifically, the particle diameter of the scattering particles is larger, the scattering performance is better, while the density of the scattering particles is larger, the transmittance is lower and the scattering performance is better. Thus, when the serration picture is slight, particles having a small particle diameter and a small density are selected, and when the serration picture is severe, particles having a large particle diameter and a large density are selected. The scattering particles having a particle diameter of 5 um to 100 um are generally selected, but no scattering particles having an excessively large particle diameter should be selected. Selection is based on actual needs. The scattering particles having a density of 10% to 40% are generally selected, but no scattering particles having an excessively high density should be selected. The scattering particles are selected as long as suitable.

S140: coating the scattering particles on a surface of the cover plate according to the laying region, the particle diameter, and the density of the scattering particles to be laid.

By scattering of the scattering particles, the luminance of the display picture on the edge display region is reduced, thereby the serration feeling of the display picture of the edge display region is improved.

Specifically, the scattering particles are coated on the surface of the cover plate according to the laying region, the particle diameter, and the density of the scattering particles to be laid. More specifically, the scattering particles are coated on the surface of the cover plate facing towards the light-emitting structure, i.e., a lower surface of the cover plate. In other embodiments, the scattering particles may also be coated on a surface of the cover plate facing away from the light-emitting structure, that is, an upper surface of the cover plate, which is not limited thereto.

Each of the technical features of the above-described embodiments may be combined arbitrarily. To simplify the description, not all of the possible combinations of each of the technical features in the above embodiments are described. However, all of the combinations of these technical features should be considered as within the scope of the present application, as long as such combinations do not contradict with each other.

The above-described embodiments merely represent several embodiments of the present application, and the description thereof is more specific and detailed, but it should not be construed as limiting the scope of the present application. It should be noted that, for a person skilled in the art, several variations and improvements may be made without departing from the concept of the present application, and these are all within the protection scope of the present application. Therefore, the protection scope of the present application shall be subject to the appended claims.

What is claimed is:

1. A display screen, wherein
the display screen comprises a contour line, and an active display region,
the active display region comprises an edge display region close to the contour line and a main display region away from the contour line, and
the edge display region and the contour line are intersected; and
wherein the display screen comprises a light-emitting layer and a light-outputting layer having a first region,
the first region of the light-outputting layer has a scattering structure provided thereon,
light emitted from the light-emitting layer is deviated from an original propagation direction after passing through the scattering structure, and
the first region is formed into at least a partial region of the light-outputting layer corresponding to the edge display region.

2. The display screen according to claim 1, wherein a projection of the first region on a substrate of the display screen is a first projection, a projection of the edge display region on the substrate of the display screen is a second projection, and the first projection overlaps the second projection.

3. The display screen according to claim 1, wherein a projection of the first region on a substrate of the display screen is a first projection, a projection of the edge display region located outside a defined region of the contour line on the substrate of the display screen is a third projection, and the first projection overlaps the third projection.

4. The display screen according to claim 1, wherein the display screen is a top light-emitting structure, and the light-outputting layer is at least one of a light extraction layer, a negative electrode, and a top cover plate; or the display screen is a bottom light-emitting structure, and the light-outputting layer is a positive electrode and/or a bottom cover plate.

5. The display screen according to claim 4, wherein the display screen is the top light-emitting structure, when the light-outputting layer is the light extraction layer, the scattering structure is a concave-convex structure or a scattering particle layer provided on the first region of the light extraction layer; when the light-outputting layer is the negative electrode, the scattering structure is a concave-convex structure or a scattering particle layer provided on the first region of the negative electrode; and when the light-outputting layer is the top cover plate, the scattering structure is a concave-convex structure or a scattering particle layer provided on the first region of the top cover plate;
or the display screen is the bottom light-emitting structure, when the light-outputting layer is the positive electrode, the scattering structure is a concave-convex structure or a scattering particle layer provided on the first region of the positive electrode; and when the light-outputting layer is the bottom cover plate, the scattering structure is a concave-convex structure or a scattering particle layer provided on the first region of the bottom cover plate.

6. The display screen according to claim 5, wherein the scattering structure is the concave-convex structure provided on the first region of the light-outputting layer, the concave-convex structure is formed on the light-outputting layer by an embossing or etching process, or the scattering structure is the scattering particle layer provided on the first region of the light-outputting layer, and the scattering particle layer is one or more of organic silicone, polyethylene, acrylic resin, nano-barium sulfate, silicon dioxide and calcium carbonate, and the scattering particle layer is formed on a surface of the light-outputting layer by an evaporation process.

7. The display screen according to claim 6, wherein a scattering effect of the scattering structure is in direct proportion to a particle diameter of scattering particles of the scattering particle layer, and the scattering effect of the scattering particles of the scattering structure is in direct proportion to a density of the scattering particle layer.

8. The display screen according to claim 7, wherein the particle diameter of the scattering particles of the scattering particle layer ranges from 5 um to 100 um.

9. The display screen according to claim 7, wherein the density of the scattering particles of the scattering particle layer ranges from 10% to 40%.

10. The display screen according to claim 1, wherein the scattering structure is provided on a surface of the light-outputting layer facing towards or facing away from a surface of the light-emitting layer.

11. The display screen according to claim 1, wherein a normal distance between the edge display region and the contour line is greater than 0 mm and less than 3 mm.

12. A display screen, wherein the display screen comprises a contour line and an active display region, the active display region comprises an edge display region close to the contour line and a main display region away from the contour line, and the edge display region and the contour line are intersected; and wherein
the display screen comprises a substrate, a light-emitting structure and a cover plate, the light-emitting structure is formed on the substrate, and covered over by the cover plate, at least a part of the edge display region is provided with a scattering layer, and the scattering layer is provided on a surface of the cover plate.

13. The display screen according to claim 12, wherein the scattering layer is provided on the surface of the cover plate facing towards or facing away from a surface of the light-emitting structure.

14. The display screen according to claim 12, wherein a normal distance between the edge display region and the contour line is greater than 0 mm and less than 3 mm.

15. The display screen according to claim 12, wherein the scattering layer is provided on the cover plate corresponding to a region of the edge display region located outside a defined region of the contour line.

16. The display screen according to claim 12, wherein the scattering layer is a scattering particle layer provided on the cover plate, and the scattering particle layer is one or more of organic silicone, polyethylene, acrylic resin, nano-barium sulfate, silicon dioxide and calcium carbonate.

17. The display screen according to claim 16, wherein a scattering effect of the scattering layer is in direct proportion to a particle diameter of scattering particles of the scattering particle layer, and the scattering effect of the scattering layer is in direct proportion to a density of the scattering particles.

18. The display screen according to claim 17, wherein the particle diameter of the scattering particles ranges from 5 um to 100 um.

19. The display screen according to claim 17, wherein the density of the scattering particles ranges from 10% to 40%.

20. A method for manufacturing a display screen, configured to manufacture a display screen, and comprising:
providing a substrate on which a light-emitting structure is provided;
positioning a cover plate over the light-emitting structure, and determining a laying region of scattering particles to be laid and an adjusting degree to a display picture of an edge display region, according to a display condition of the edge display region of the light-emitting structure;
determining a particle diameter and a density of the scattering particles to be laid according to the laying region of the scattering particles to be laid and the adjusting degree; and
coating the scattering particles on a surface of the cover plate according to the laying region, the particle diameter, and the density of the scattering particles to be laid, to reduce an luminance of the display picture of the edge display region.
